(19) United States
(12) Patent Application Publication
(10) Pub. No.: US 2023/0401365 A1
(43) Pub. Date: Dec. 14, 2023

(54) DETERMINING CELL PROPERTIES FOR A GRID GENERATED FROM A GRID-LESS MODEL OF A RESERVOIR OF AN OILFIELD

(71) Applicant: Landmark Graphics Corporation, Houston, TX (US)

(72) Inventor: Mehran Hassanpour, Houston, TX (US)

(21) Appl. No.: 17/840,393

(22) Filed: Jun. 14, 2022

(51) Int. Cl. G06F 30/28

(52) U.S. Cl. CPC G06F 30/28

(57) ABSTRACT

A system can receive a grid-less point cloud model of a geological formation, the grid-less cloud point model that includes data points. The system can determine, by a machine-learning model for clustering data points, clusters for the data points according to a heterogeneity index. The system can determine an outline for each cluster. The system can generate a grid corresponding to the geological formation, the grid comprising a plurality of cells for each cluster of the plurality of clusters, each cluster having cell properties. The system can output the grid for the geological formation to a graphical user interface, the grid usable for executing a flow simulation at the graphical user interface.

### TECHNICAL FIELD

The present disclosure relates generally to wellbore operations and, more particularly (although not necessarily exclusively), to determining cell properties for a grid generated from a grid-less model of a reservoir of an oilfield.

### BACKGROUND

A wellbore can be formed in a subterranean formation for extracting various material such as hydrocarbon material. The subterranean formation may include one or more geological formations that include the hydrocarbon material. An exploration operation can involve determining hydrocarbon well placement locations with respect to the subterranean formation. Hydrocarbon well performance can be affected by the presence of certain substances, such as sands. But, characterizing the geological formation can be difficult.

### BRIEF DESCRIPTION OF THE DRAWINGS

FIG. 1 is a sectional side-view of a well that is positioned in a subterranean formation according to one example of the present disclosure.

FIG. 2 is a block diagram of a computing device for determining cell properties for a grid corresponding to a geological formation according to one example of the present disclosure.

FIG. 3 is a set of graphs depicting clustered and unclustered data points that can be used for generating a grid corresponding to a geological formation according to one example of the present disclosure.

FIG. 4 is a graph of heterogeneity index values according to a number of clusters that can be used for determining cell properties for a grid of a geological formation according to one example of the present disclosure.

FIG. 5 is a close-up illustration of an example of a grid that can be generated according to one example of the present disclosure.

FIG. 6 is a large-scale illustration of an example of a grid that can be generated according to one example of the present disclosure.

FIG. 7 is an illustration of an example grid-less point-cloud model and a grid corresponding to the grid-less point cloud model according to one example of the present disclosure.

FIG. 8 is a flow diagram of a process for determining cell properties for a grid corresponding to a geological formation according to one example of the present disclosure.

### DETAILED DESCRIPTION

Certain aspects and features of the present disclosure relate to determining cell properties for a grid corresponding to a geological formation. The geological formation can include a porous and permeable subsurface body of rock, such as a reservoir, that can accumulate and store hydrocarbons, such as crude oil. A wellbore can be drilled into the geological formation for extracting the hydrocarbons from the geological formation and transmitting the hydrocarbons to the surface. It may be desirable to generate a flow simulation of the geological formation to analyze properties of the geological formation and to control future wellbore operations. For example, an output of the flow simulation can indicate a range of acceptable parameters for the wellbore operation. In some examples, simulating the geological formation can include generating a grid with a number of cells. A grid of cells corresponding to the geological formation may be needed for the flow simulation. As such, cell properties of the grid may be determined so that the geological formation is accurately simulated. The cell properties can include a number of cells, a size of each cell, and a shape of each cell.

A porosity and permeability of regions in the geological formation may determine a difficulty of hydrocarbon extraction associated with the regions of the geological formation. Data associated with the porosity and permeability of the regions of the geological formation can be gathered from downhole tools and sensors that can be deployed in or around the geological formation. For example, the data points can include log data obtained from a wireline log. The data points can include coordinates associated with the location within the geological formation from which the data was obtained. The data can be represented, according to the coordinates, as a three-dimensional model, such as a grid-less point cloud model. In some examples, the data can be represented as a high-resolution geological grid. The high-resolution geological grid can be upscaled to increase the resolution of the high-resolution geological grid. Properties of the regions of the geological formation can be modeled at each point of the grid-less point cloud model. The properties of the geological formation modeled by the grid-less point cloud model can include a presence score, a porosity, a permeability, or any other suitable property. The presence score may indicate a probability of sand being present at the location.

Upon receiving the grid-less point cloud model, a computing device can use a machine-learning model to group the data points of the grid-less point cloud model into clusters. The number of clusters to group the data points into may be determined based on a heterogeneity index. In some examples, the computing device can determine cell properties of the grid based on heterogeneity index values of each of the clusters of point-cloud data. So, different clusters may have different cell properties based on their respective heterogeneity index values. Determining the cell properties based on the heterogeneity index values can decrease a number of cells involved in adequately simulating the geological formation in the flow simulation. Adequate simulation of the geological formation can decrease a runtime of the flow simulation, which can prevent unnecessary uses of computing resources and network bandwidth. Additionally or alternatively, determining the cell properties of the grid based on the outlines of the clusters can enable property modeling prior to a runtime of the simulation.

Once the clusters are determined, the computing device can determine an outline for each cluster. The outlines can be determined with an alpha shape algorithm. Each outline can correspond to a group of cells in the grid. For each outline, the computing device can determine cell properties for the group of cells corresponding to the outline. For example, the computing device can use the heterogeneity index values of each cluster to determine the shapes and sizes of the cells as well as the number of cells in each cluster. The computing device can use the cell properties to generate the grid. The computing device can then run a flow simulation using the grid and display a result of the flow simulation at a graphical user interface. In some examples, the computing device can compare an output of the flow simulation to an objective function. The computing device can adjust the cell properties of the grid based on the output. Additionally or alternatively, the output of the flow simulation can be used to control a wellbore operation, such as a wellbore drilling operation or a wellbore completion operation.

Illustrative examples are given to introduce the reader to the general subject matter discussed herein and are not intended to limit the scope of the disclosed concepts. The following sections describe various additional features and examples with reference to the drawings in which like numerals indicate like elements, and directional descriptions are used to describe the illustrative aspects, but, like the illustrative aspects, should not be used to limit the present disclosure.

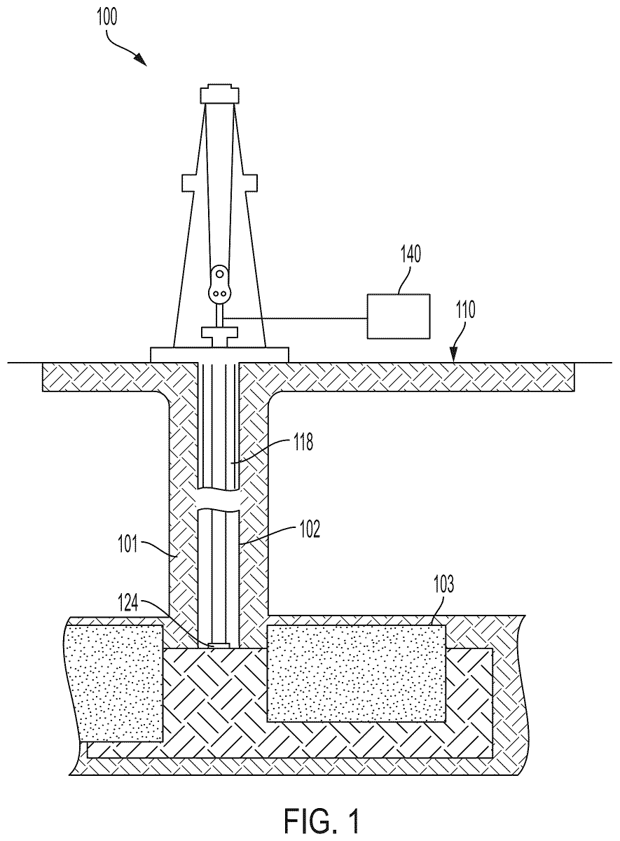

FIG. 1 is a sectional side-view of a well 100 positioned in a subterranean formation 101 that includes a geological formation 103 beneath a surface 110 according to one example of the present disclosure. The geological formation 103 may be a reservoir that can contain hydrocarbons, such as crude oil. The geological formation 103 may be encapsulated by, or otherwise dispersed within, the subterranean rock formation 101. The well 100 may include a wellbore 102 that can be drilled into, or otherwise formed in, the subterranean formation 101 for accessing the geological formation 103. The well 100 may extract hydrocarbons from the geological formation 103. A difficulty associated with extracting the hydrocarbons from the geological formation 103 may depend on a heterogeneity of the geological formation 103. The heterogeneity can indicate a variability of rock properties in the geological formation 103. For example, rock properties in a heterogeneous geological formation 103 can vary more dramatically among different regions of the geological formation 103 than rock properties in a homogeneous geological formation 103. In some examples, a heterogeneous geological formation may be more to extract material from than a homogeneous geological formation. Geological formations that can be difficult to extract hydrocarbons from may result in an increased carbon intensity. Accordingly, production-related wellbore operations in heterogeneous geological formations may cause more carbon emissions than production-related wellbore operations in homogeneous geological formations to produce similar units of energy.

The wellbore 102 may include a wireline 118 that can be used to lift or lower equipment, such as a sensor 124. The sensor 124 may be communicatively coupled, by the wireline 118, to a computing device 140 that can be used to generate a wireline log. In some examples, the wireline log can include a record of continuous measurements that can be related to formation properties of the geological formation 103 that can be taken by the sensor 124. The sensor 124 may be coupled to a logging tool that can be positioned downhole and coupled to the wireline 118 for lifting or lowering the logging tool in the wellbore 102. In some examples, the wireline log can include electrical measurements, sonic measurements, nuclear measurements, caliper measurements, formation fluid measurements, rheological measurements, pressure measurements, porosity measurements, permeability measurements, or any combination thereof. It may be desirable to generate a flow simulation of the geological formation 103 for controlling wellbore operations. The flow simulation may involve generating a grid of cells, each of which may be associated with a set of cell properties.

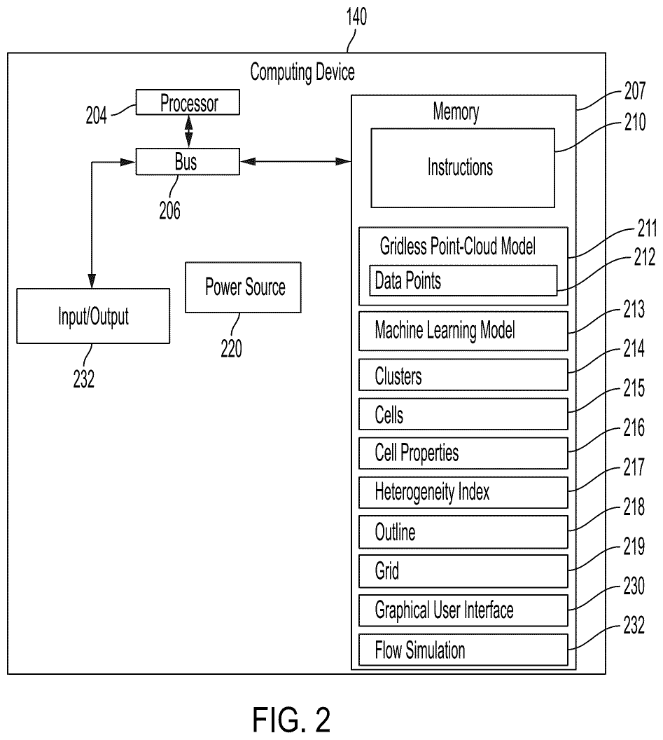

FIG. 2 is a block diagram of a computing device 140 that can be used for determining cell properties 216 for a grid 219 corresponding to a geological formation according to one example of the present disclosure. The components shown in FIG. 2, such as a processor 204, memory 207, power source 220, communications device 201, and the like may be integrated into a single structure such as within a single housing of a computing device 140. Alternatively, the components shown in FIG. 2 can be distributed from one another and in electrical communication with each other.

The computing device 140 can include the processor 204, the memory 207, and the bus 206. The processor 204 can execute one or more operations for determining the cell properties 216 for the grid 219 corresponding to the geological formation. The processor 204 can execute instructions 210 stored in the memory 207 to perform the operations. The processor 204 can include one processing device or multiple processing devices or cores. Non-limiting examples of the processor 204 include a Field-Programmable Gate Array (“FPGA”), an application-specific integrated circuit (“ASIC”), a microprocessor, etc.

The processor 204 can be communicatively coupled to the memory 207 via the bus 206. The non-volatile memory 207 may include any type of memory device that retains stored information when powered off. Non-limiting examples of the memory 207 may include EEPROM, flash memory, or any other type of non-volatile memory. In some examples, at least part of the memory 207 can include a medium from which the processor 204 can read instructions 210. A computer-readable medium can include electronic, optical, magnetic, or other storage devices capable of providing the processor 204 with computer-readable instructions or other program code. Non-limiting examples of a computer-readable medium include (but are not limited to) magnetic disk(s), memory chip(s), ROM, RAM, an ASIC, a configured processor, optical storage, or any other medium from which a computer processor can read instructions. The instructions 210 can include processor-specific instructions generated by a compiler or an interpreter from code written in any suitable computer-programming language, including, for example, C, C++, C#, etc. The computer program instructions 210 can be executed by the processor 204 for causing the processor 204 to perform various operations.

The computing device 140 can receive a grid-less point cloud model 211 that corresponds to the geological formation, such as the geological formation 100 in FIG. 1. While aspects of the present disclosure describe an approach using the grid-less point cloud model 211, a similar approach may be performed upon receiving a high-resolution geological grid that corresponds to the geological formation. The grid-less point cloud model 211 can include data points 212. For example, the data points 212 can include coordinates that may associate each of the data points 212 with unique locations in the geological formation 100. In some examples, the data points 212 can include data from a wireline log that can be gathered by a sensor 124 in a wellbore. The data points 212 in the grid-less point cloud model 211 can indicate a property of the geological formation 100, such as porosity, permeability, or a presence score. For example, the presence score can indicate a probability that a certain substance, such as sand, will be present in a location associated with the presence score.

In some examples, the memory 207 can include a machine-learning model 213. The computing device 140 can execute the machine-learning model 213 to group the data points 212 of the grid-less point cloud model 211 into clusters 214. The machine-learning model 213 can include a k-means clustering algorithm, a spectral clustering algorithm, an agglomerative clustering algorithm, or a Ward clustering algorithm. In some examples, the machine-learning model 213 can include a supervised learning algorithm, such as neural network model that can be trained on historical data. For example, the historical data can include sets of data related to previous wellbore operations that can correspond to previously-explored geological formations. In some examples, the machine-learning model 213 can cluster data in the historical data. The machine-learning model 213 can iteratively adjust parameters of the machine-learning model 213 based on an output value that the machine-learning model 213. The computing device 140 can execute the machine-learning model 213 and adjust the parameters based on the output value until the output value is stable or reaches a desired value.

In some examples, the machine-learning model 213 can generate the clusters 214 based on a parameter, such as a heterogeneity index 217. For example, the number of clusters 214 can be adjusted with respect to the total heterogeneity index 217 associated with the grid-less point cloud model 211. In some examples, a user can select a desired threshold for the heterogeneity index 217 so that heterogeneity of the grid-less point cloud model 211 is preserved in the clusters 214. The threshold may be expressed as a desired fraction of a total heterogeneity index 217 of the grid 219 and a heterogeneity of the grid-less point cloud model 211. In other words, a threshold of 1.0 can indicate a 1:1 correlation between the total heterogeneity index 217 of the grid 219 and the total heterogeneity index value of the grid-less point cloud model 211.

The computing device 140 can determine a number of clusters such that the total heterogeneity index of the clusters 214 is similar to the total heterogeneity index 217 of the grid-less point cloud model 211. The processor 204 can select the number of clusters such that the clusters 214 satisfy the threshold for the total heterogeneity index 217 value. The machine-learning model 214 can then group the data points 212 into the determined number of clusters.

In some examples, the processor 204 can determine an outline 218 for each of the clusters 214. In some examples, the processor 204 can use an alpha shape algorithm to determine the outline 218. Each outline 218 can represent an outer boundary of each cluster 214, such that each cluster 214 is contained within its respective outline 218. Each cluster 214 can correspond to a group of cells 215 of the grid 219. The processor 204 can use the heterogeneity index 217 of each cluster 214 to determine cell properties 216 for the each of the groups of cells 215. For example, the processor 204 can use a first heterogeneity index value of a first cluster to determine a shape (e.g., square, rectangular, trapezoidal, triangular, or any other suitable shape), number, and size of a first group of cells 215 associated with the first cluster. The processor 204 can also use a second heterogeneity index value of a second cluster to determine a shape, number, and size of a second group of cells 215 associated with the second cluster. The cell properties 216 for the first cluster may be the same or different than the cell properties 216 for the second cluster. As an example, a higher heterogeneity index value may result in a higher number of and smaller sized cells than a lower heterogeneity index value. In some examples, the computing device 140 can include a second machine-learning model for determining the cell properties 216 for the groups of cells 215 based on the heterogeneity index 217. For example, the second machine-learning model can be trained to optimize the cell properties 216 for a given heterogeneity index 217 based on historical data. The second machine-learning model can be trained on a training dataset of previous groups of cells 215 and previous optimal cell properties 216 corresponding to the previous groups of cells 215.

The computing device 140 can use the cell properties 216 of each cell 215 to generate the grid 219. The grid 219 can include each group of cells 215 corresponding to each of the cluster 214, where each cluster 214 has the determined cell properties 216 for the cluster 214. The grid 219 can be a discrete representation of the geological formation. The grid 219 can be used by the computing device 140 to run a flow simulation 232. The flow simulation 232 can simulate a flow of a fluid through the geological formation 100. Upon running the flow simulation 232, the computing device 140 can determine a value of an objective function by evaluating an output of the flow simulation 232. The computing device 140 can use the result of the flow simulation 232 to adjust the grid 219. For example, the objective function can indicate a difference between production data obtained from the geological formation and the output from the flow simulation 232. Based on the value of the objective function, the processor 203 can adjust the cell properties for cells 215 associated with the clusters 214. For instance, a particular value for the objective function may indicate that the size of the cells in a cluster are to be increased. Updated cell properties can be used to generate an updated grid having groups of updated cells that correspond to the updated cell properties. Another flow simulation can be executed for the updated grid. The objective function can be re-evaluated each time the grid 219 is updated until the objective function returns a stable, minimized, or otherwise satisfactory value.

The output of the flow simulation 232 can be displayed on a graphical user interface 230. For example, the graphical user interface 230 can display the flow simulation 232 as a heatmap. As an example, the heatmap can display regions of the geological formation that are more susceptible to fluid flow in a first color (e.g., red), and regions that are less susceptible to fluid flow in a second color (e.g., blue). The heatmap may include a gradient of colors that can enable a user to determine an amount of simulated fluid flow at a location on the heatmap, and thus a corresponding location in the geological formation, based on the color displayed at the location.

In some examples, the computing device 140 can include a power source 220. The power source 220 can be in electrical communication with the computing device 140 and the communications device 201. In some examples, the power source 220 can include a battery or an electrical cable (e.g., a wireline). The power source 220 can include an alternating current signal generator. The computing device 140 can operate the power source 220 to apply a transmission signal to the antenna 228 to generate electromagnetic waves that convey data to other systems. For example, the computing device 140 can cause the power source 220 to apply a voltage with a frequency within a specific frequency range to the antenna 228. This can cause the antenna 228 to generate a wireless transmission. In other examples, the computing device 140, rather than the power source 220, can apply the transmission signal to the antenna 228 for generating the wireless transmission. For example, the computing device 140 can transmit, via the antenna 228, instructions for controlling the wellbore drilling operation.

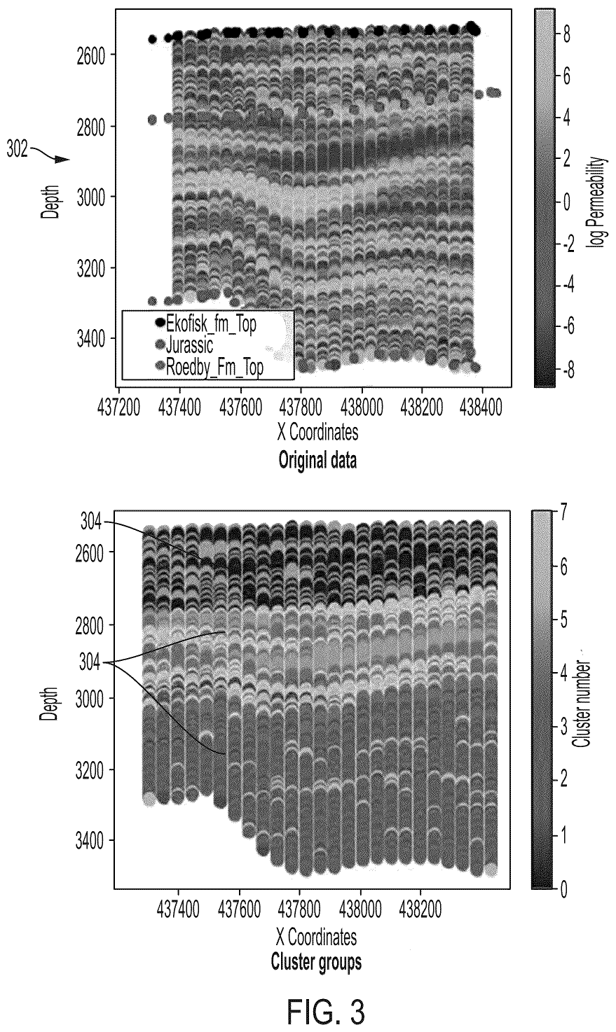

FIG. 3 is a set of graphs depicting clustered and unclustered data points that can be used for generating a grid corresponding to a geological formation according to one example of the present disclosure. In some examples, a computing device can cluster data points 302 from a grid-less point cloud model clusters 304. The computing device can determine a number of clusters based on a heterogeneity index of the cluster and a heterogeneity threshold that can be selected by a user. Upon determining the number of clusters, the computing device can use a machine-learning model to generate the clusters 304. In the example depicted in FIG. 3, seven clusters 304 are shown.

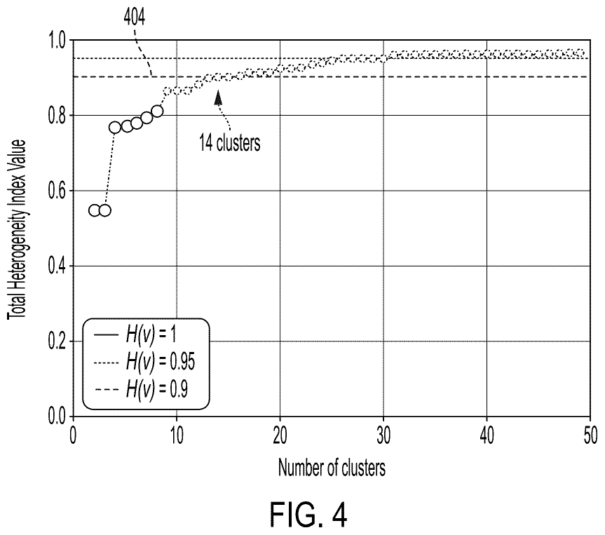

FIG. 4 is a graph of total heterogeneity index values according to a number of clusters that can be used for determining cell properties according to one example of the present disclosure. Adjusting the number of clusters can result in changes to the total heterogeneity index value of the grid. A user may provide a threshold for a satisfactory total heterogeneity index value. The threshold can be expressed as a desired fraction of a total heterogeneity index value of a grid-less point cloud model of a geological formation to a total heterogeneity index value of a grid generated based on the grid-less point cloud model. In other words, a threshold of 1.0 can indicate a 1:1 correlation between the total heterogeneity index value of the grid and the total heterogeneity index value of the grid-less point cloud model.

In the example depicted in FIG. 4, a threshold 404 is set at 0.9. If the number of clusters is set too low, the threshold 404 may not be met, and the characteristics of the geological formation may not be sufficiently preserved. As illustrated in the example in FIG. 4, fourteen clusters are sufficient for the total heterogeneity index value of the clusters to meet the threshold 404. Selecting a number of clusters greater than the number required to meet the threshold 404 can result in an increase in preserved characteristics, but may also consume additional computing resources when generating the grid and executing a flow simulation. Therefore, the number of clusters can be selected as fourteen to satisfy the threshold 404 without negatively affecting the amount of computing resources that are consumed to generate the clusters and the grid.

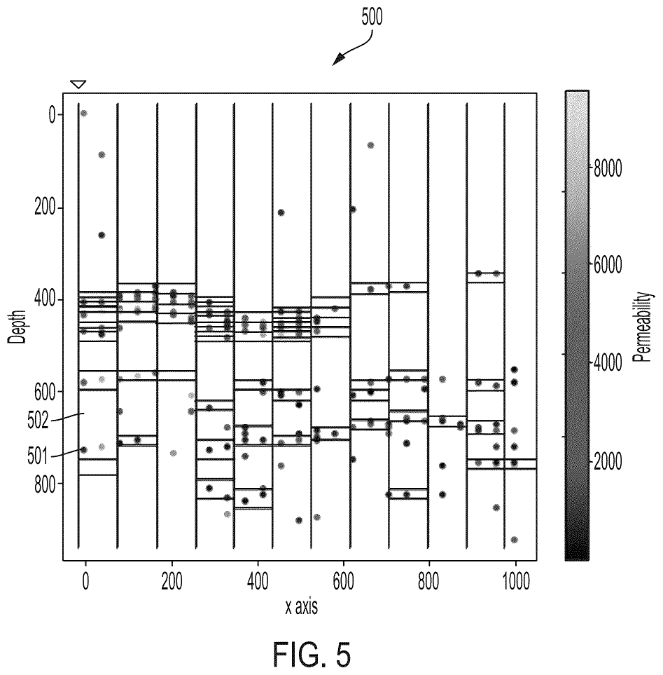

FIG. 5 is a close-up illustration of an example of a grid 500 that can be generated according to one example of the present disclosure. The grid 500 can include a set of cells 502 corresponding to data points 501. Each cluster of cells 502 may have a corresponding set of cell properties, where each cluster is determined by a machine-learning model. The cell properties can include a shape and size of the cell. The cell properties can be determined with respect to an outline of clustered data points 501 and a heterogeneity index value associated with the cluster.

In the example depicted in FIG. 5, the groups of cells 502 representing a cluster are rectangular in shape. A computing device can generate the grid 500 for representing at least a portion of a geological formation in a flow simulation. Depending on their respective heterogeneity index values, some clusters can be assigned larger cells than other clusters, or a different number of cells than other clusters. The flow simulation can use the grid 500 to simulate a flow of a fluid through the geological formation.

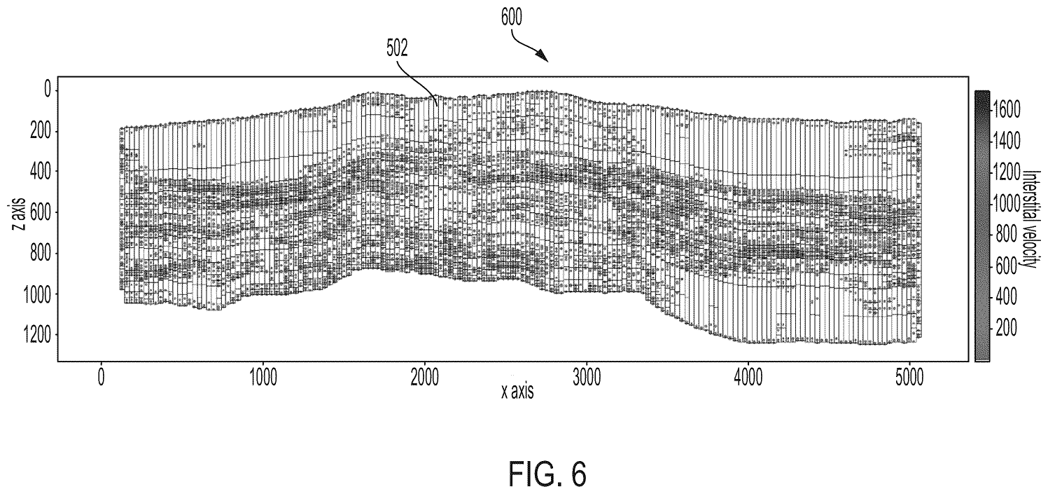

FIG. 6, illustrates a grid 600, which is a zoomed-out version of grid 500. So, the grid 600 includes more cells 502 of more clusters than grid 500. The grid 600 can represent an entirety of the geological formation represented in the grid-less point cloud model.

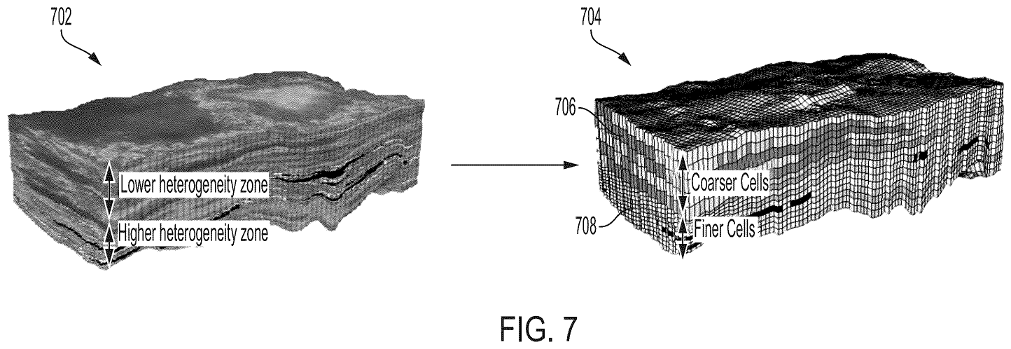

FIG. 7 is an illustration of example grid-less point cloud model 702 and a grid 704 generated based on to the grid-less point cloud model 702 according to one example of the present disclosure. The grid-less point cloud model 702 can include data points that indicate spatial information such as a location of each point in space, as well as information related to a property of the geographical formation at the location of the data point. The grid-less point cloud model 702 can be displayed on a graphical user interface as a heatmap, where colors correspond to different values of the property. A computing device can generate the grid 704 based on clusters of data points in the grid-less point cloud model 702. For example, the computing device can use a machine-learning model to cluster data points into clusters. The computing device can use an alpha shape algorithm to generate outlines of the clusters. The computing device can then use the outlines of the clusters to determine the grid 704, such that each outline can correspond to a cluster in the grid 704. A first cluster 706 with a low heterogeneity index may be assigned larger cells than a second cluster 708 with a high heterogeneity index. Assigning cell properties to groups of cells based on the heterogeneity index of their corresponding clusters can enable the grid 704 to model more complicated features of the geological formation with a higher resolution, and minimize the amount of computing resources necessary to model simpler features of the geological formation.

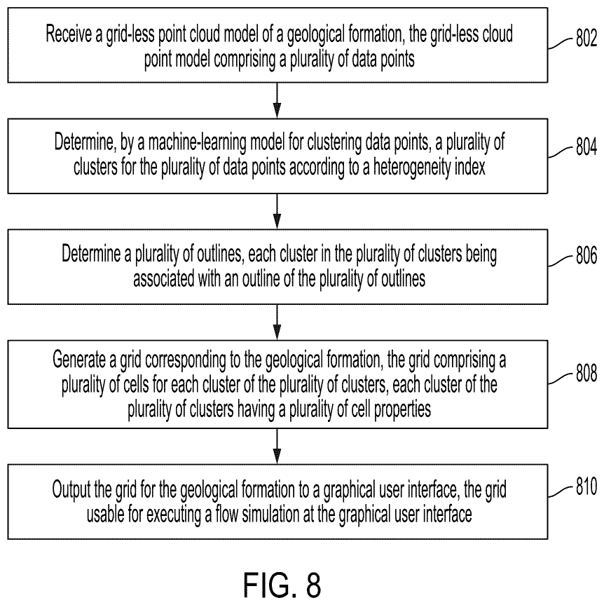

FIG. 8 is a flow diagram of a process for determining cell properties for a grid corresponding to a geological formation according to one example of the present disclosure. At block 802, a computing device can receive a grid-less point cloud model of a geological formation. The grid-less cloud point model can include a plurality of data points. In some examples, the data points can be retrieved from one or more wireline logs. The wireline logs can include data from sensors that can be positioned downhole in one or more wellbores. For example, the data points can include electrical measurements, sonic measurements, nuclear measurements, caliper measurements, formation fluid measurements, rheological measurements, pressure measurements, porosity measurements, permeability measurements, or any combination thereof. The data points can include coordinates that can associate the data points with a location in space. The grid-less point cloud model can be displayed by arranging the data points with respect to their coordinates.

At block 804, the computing device can determine, by a machine-learning model for clustering data points, a plurality of clusters for the plurality of data points according to a heterogeneity index of the clusters. In some examples, the machine-learning model can include an unsupervised clustering algorithm that may not involve training or a training dataset. Such clustering algorithms can include a k-means clustering algorithm, an agglomerative clustering algorithm, or a Ward clustering algorithm. Additionally or alternatively, the machine-learning model can include a supervised clustering algorithm that can be trained on a training dataset of historical data. The computing device can select the number of clusters to satisfy a desired threshold for a heterogeneity index value of the clusters.

At block 806, the computing device can determine a set of outlines. Each cluster in the set of clusters can be associated with an outline of the set of outlines. Each outline can represent an outer boundary of each cluster, such that each cluster is contained within its respective outline. The computing device can determine the outlines with an alpha shape algorithm.

At block 808, the computing device can generate a grid corresponding to the geological formation. The grid can have a set of cells for each cluster of the set of clusters, and each cluster in the set of clusters can be associated with a set of cell properties. In some examples, the cell properties can include a size of the cells, a number of the cells, and a shape of each cell in the set of cells. The grid can be a discrete representation of the geological formation, where each set of cells can represent a unique region of the geological formation.

At block 810, the computing device can output the grid for the geological formation to a graphical user interface. The grid can be usable for executing a flow simulation at the graphical user interface. The flow simulation can simulate a flow of a fluid through the geological formation. For example, the flow simulation can simulate a flow of hydrocarbons, drilling fluids, water, or any other suitable fluid through the geological formation. The graphical user interface can include a heatmap that can use colors to help a user visualize the simulated flow of fluids in the flow simulation. For example, one group of colors may correspond to regions of high fluid pressure and a second group of colors may correspond to regions of low fluid pressure.

In some aspects, system, method, and non-transitory computer-readable medium for cell properties for a grid corresponding to a geological formation by determining outlines of clustered data based on a heterogeneity index are provided according to one or more of the following examples:

As used below, any reference to a series of examples is to be understood as a reference to each of those examples disjunctively (e.g., “Examples 1-4” is to be understood as “Examples 1, 2, 3, or 4”).

Example 1 is a system comprising: a processor; and a memory that includes instructions executable by the processor for causing the processor to: receive a grid-less point cloud model of a geological formation, the grid-less cloud point model comprising a plurality of data points; determine, by a machine-learning model for clustering data points, a plurality of clusters for the plurality of data points according to a heterogeneity index; determine a plurality of outlines, each cluster in the plurality of clusters being associated with an outline of the plurality of outlines; generate a grid corresponding to the geological formation, the grid comprising a plurality of cells for each cluster of the plurality of clusters, each cluster of the plurality of clusters having a plurality of cell properties; and output the grid for the geological formation to a graphical user interface, the grid usable for executing a flow simulation at the graphical user interface.

Example 2 is the system of example(s) 1, wherein the instructions are further executable by the processor for causing the processor to determine, based on the heterogeneity index, the plurality of cell properties for each cluster of the plurality of clusters, wherein the plurality of cell properties comprise a cell size, a number of cells, and a cell shape.

Example 3 is the system of example(s) 1, wherein the instructions are further executable by the processor for causing the processor to: determine a value of an objective function based on the flow simulation; determine, based on the value of the objective function, a plurality of updated cell properties for the plurality of cells; generate, an updated grid comprising a plurality of updated cells having the plurality of updated cell properties; and output the updated grid for the geological formation to the graphical user interface, the updated grid usable for executing another flow simulation at the graphical user interface.

Example 4 is the system of example(s) 1, wherein the instructions are further executable by the processor for causing the processor to: determine a first heterogeneity parameter of the heterogeneity index for a first cluster of the plurality of clusters corresponds to a first number of cells and a first cell size for the first cluster; and determine a second heterogeneity parameter of the heterogeneity index for a second cluster of the plurality of clusters corresponds to a second number of cells and a second cell size for the second cluster.

Example 5 is the system of example(s) 1, wherein the machine-learning model is a k-means clustering algorithm, a spectral clustering algorithm, an agglomerative clustering algorithm, or a Ward clustering algorithm.

Example 6 is the system of example(s) 1, wherein the instructions are further executable by the processor for causing the processor to determine the plurality of outlines for the plurality of clusters via an alpha shape algorithm.

Example 7 is the system of example(s) 1, wherein the instructions are further executable by the processor for causing the processor to determine, by another machine-learning model, the plurality of cell properties for the plurality of cells based on the heterogeneity index.

Example 8 is a method comprising: receiving, by a processor, a grid-less point cloud model of a geological formation, the grid-less cloud point model comprising a plurality of data points; determining, by the processor and a machine-learning model for clustering data points, a plurality of clusters for the plurality of data points according to a heterogeneity index; determining, by the processor, a plurality of outlines, each cluster in the plurality of clusters being associated with an outline of the plurality of outlines; generating, by the processor, a grid corresponding to the geological formation, the grid comprising a plurality of cells for each cluster of the plurality of clusters, each cluster of the plurality of clusters having a plurality of cell properties; and outputting, by the processor, the grid for the geological formation to a graphical user interface, the grid usable for executing a flow simulation at the graphical user interface.

Example 9 is the method of example(s) 8, further comprising: determining, based on the heterogeneity index, the plurality of cell properties for each cluster of the plurality of clusters, wherein the plurality of cell properties comprise a cell size, a number of cells, and a cell shape.

Example 10 is the method of example(s) 8, further comprising: determining, by the processor, a value of an objective function based on the flow simulation; determining, by the processor and based on the value of the objective function, a plurality of updated cell properties for the plurality of cells; generating, by the processor, an updated grid comprising a plurality of updated cells having the plurality of updated cell properties; and outputting, by the processor, the updated grid for the geological formation to the graphical user interface, the updated grid usable for executing another flow simulation at the graphical user interface.

Example 11 is the method of example(s) 8, further comprising: generating, by the processor, the graphical user interface based on the grid-less point cloud model, wherein the graphical user interface is configured to display a quantity at various spatial locations as a heat map.

Example 12 is the method of example(s) 8, wherein the machine-learning model is a k-means clustering algorithm, a spectral clustering algorithm, an agglomerative clustering algorithm, or a Ward clustering algorithm.

Example 13 is the method of example(s) 8, further comprising: determining, by the processor, the plurality of outlines for the plurality of clusters via an alpha shape algorithm.

Example 14 is the method of example(s) 8, further comprising: determining, by another machine-learning model, the plurality of cell properties for the plurality of cells based on the heterogeneity index.

Example 15 is the method of example(s) 8, further comprising: determining, by the processor, a first heterogeneity parameter of the heterogeneity index for a first cluster of the plurality of clusters corresponds to a first number of cells and a first cell size for the first cluster; and determining, by the processor, a second heterogeneity parameter of the heterogeneity index fora second cluster of the plurality of clusters corresponds to a second number of cells and a second cell size for the second cluster.

Example 16 is a non-transitory computer readable medium comprising instructions executable by a processor for causing the processor to: receive a grid-less point cloud model of a geological formation, the grid-less cloud point model comprising a plurality of data points; determine, by a machine-learning model for clustering data points, a plurality of clusters for the plurality of data points according to a heterogeneity index; determine a plurality of outlines, each cluster in the plurality of clusters being associated with an outline of the plurality of outlines; generate a grid corresponding to the geological formation, the grid comprising a plurality of cells for each cluster of the plurality of clusters, each cluster of the plurality of clusters having a plurality of cell properties; and output the grid for the geological formation to a graphical user interface, the grid usable for executing a flow simulation at the graphical user interface.

Example 17 is the non-transitory computer readable medium of example(s) 16, wherein the instructions are further executable by the processor for causing the processor to determine, based on the heterogeneity index, the plurality of cell properties for each cluster of the plurality of clusters, wherein the plurality of cell properties comprise a cell size, a number of cells, and a cell shape.

Example 18 is the non-transitory computer readable medium of example(s) 16, further comprising instructions executable by the processor for causing the processor to: determine a value of an objective function based on the flow simulation; determine, based on the value of the objective function, a plurality of updated cell properties for the plurality of cells; generate, an updated grid comprising a plurality of updated cells having the plurality of updated cell properties; and output the updated grid for the geological formation to the graphical user interface, the updated grid usable for executing another flow simulation at the graphical user interface.

Example 19 is the non-transitory computer readable medium of example(s) 16, wherein the instructions are further executable by the processor for causing the processor to: determine a first heterogeneity parameter of the heterogeneity index for a first cluster of the plurality of clusters corresponds to a first number of cells and a first cell size for the first cluster; and determine a second heterogeneity parameter of the heterogeneity index fora second cluster of the plurality of clusters corresponds to a second number of cells and a second cell size for the second cluster.

Example 20 is the non-transitory computer readable medium of example(s) 16, wherein the instructions are further executable by the processor for causing the processor to determine, by another machine-learning model, the plurality of cell properties for the plurality of cells based on the heterogeneity index.

The foregoing description of certain examples, including illustrated examples, has been presented only for the purpose of illustration and description and is not intended to be exhaustive or to limit the disclosure to the precise forms disclosed. Numerous modifications, adaptations, and uses thereof will be apparent to those skilled in the art without departing from the scope of the disclosure.

What is claimed is:

1. A system comprising:
a processor; and
a memory that includes instructions executable by the processor for causing the processor to:
receive a grid-less point cloud model of a geological formation, the grid-less cloud point model comprising a plurality of data points;
determine, by a machine-learning model for clustering data points, a plurality of clusters for the plurality of data points according to a heterogeneity index;
determine a plurality of outlines, each cluster in the plurality of clusters being associated with an outline of the plurality of outlines;
generate a grid corresponding to the geological formation, the grid comprising a plurality of cells for each cluster of the plurality of clusters, each cluster of the plurality of clusters having a plurality of cell properties; and
output the grid for the geological formation to a graphical user interface, the grid usable for executing a flow simulation at the graphical user interface.

2. The system of claim 1, wherein the instructions are further executable by the processor for causing the processor to determine, based on the heterogeneity index, the plurality of cell properties for each cluster of the plurality of clusters, wherein the plurality of cell properties comprise a cell size, a number of cells, and a cell shape.

3. The system of claim 1, wherein the instructions are further executable by the processor for causing the processor to:
determine a value of an objective function based on the flow simulation;
determine, based on the value of the objective function, a plurality of updated cell properties for the plurality of cells;
generate, an updated grid comprising a plurality of updated cells having the plurality of updated cell properties; and
output the updated grid for the geological formation to the graphical user interface, the updated grid usable for executing another flow simulation at the graphical user interface.

4. The system of claim 1, wherein the instructions are further executable by the processor for causing the processor to:
determine a first heterogeneity parameter of the heterogeneity index for a first cluster of the plurality of clusters corresponds to a first number of cells and a first cell size for the first cluster; and
determine a second heterogeneity parameter of the heterogeneity index for a second cluster of the plurality of clusters corresponds to a second number of cells and a second cell size for the second cluster.

5. The system of claim 1, wherein the machine-learning model is a k-means clustering algorithm, a spectral clustering algorithm, an agglomerative clustering algorithm, or a Ward clustering algorithm.

6. The system of claim 1, wherein the instructions are further executable by the processor for causing the processor to determine the plurality of outlines for the plurality of clusters via an alpha shape algorithm.

7. The system of claim 1, wherein the instructions are further executable by the processor for causing the processor to determine, by another machine-learning model, the plurality of cell properties for the plurality of cells based on the heterogeneity index.

8. A method comprising:
receiving, by a processor, a grid-less point cloud model of a geological formation, the grid-less cloud point model comprising a plurality of data points;
determining, by the processor and a machine-learning model for clustering data points, a plurality of clusters for the plurality of data points according to a heterogeneity index;
determining, by the processor, a plurality of outlines, each cluster in the plurality of clusters being associated with an outline of the plurality of outlines;
generating, by the processor, a grid corresponding to the geological formation, the grid comprising a plurality of cells for each cluster of the plurality of clusters, each cluster of the plurality of clusters having a plurality of cell properties; and
outputting, by the processor, the grid for the geological formation to a graphical user interface, the grid usable for executing a flow simulation at the graphical user interface.

9. The method of claim 8, further comprising:
determining, based on the heterogeneity index, the plurality of cell properties for each cluster of the plurality of clusters, wherein the plurality of cell properties comprise a cell size, a number of cells, and a cell shape.

10. The method of claim 8, further comprising:
determining, by the processor, a value of an objective function based on the flow simulation;
determining, by the processor and based on the value of the objective function, a plurality of updated cell properties for the plurality of cells;
generating, by the processor, an updated grid comprising a plurality of updated cells having the plurality of updated cell properties; and
outputting, by the processor, the updated grid for the geological formation to the graphical user interface, the updated grid usable for executing another flow simulation at the graphical user interface.

11. The method of claim 8, further comprising:
generating, by the processor, the graphical user interface based on the grid-less point cloud model, wherein the graphical user interface is configured to display a quantity at various spatial locations as a heat map.

12. The method of claim 8, wherein the machine-learning model is a k-means clustering algorithm, a spectral clustering algorithm, an agglomerative clustering algorithm, or a Ward clustering algorithm.

13. The method of claim 8, further comprising:
determining, by the processor, the plurality of outlines for the plurality of clusters via an alpha shape algorithm.

14. The method of claim 8, further comprising:
determining, by another machine-learning model, the plurality of cell properties for the plurality of cells based on the heterogeneity index.

15. The method of claim 8, further comprising:
determining, by the processor, a first heterogeneity parameter of the heterogeneity index for a first cluster of the plurality of clusters corresponds to a first number of cells and a first cell size for the first cluster; and
determining, by the processor, a second heterogeneity parameter of the heterogeneity index for a second cluster of the plurality of clusters corresponds to a second number of cells and a second cell size for the second cluster.

16. A non-transitory computer readable medium comprising instructions executable by a processor for causing the processor to:
receive a grid-less point cloud model of a geological formation, the grid-less cloud point model comprising a plurality of data points;
determine, by a machine-learning model for clustering data points, a plurality of clusters for the plurality of data points according to a heterogeneity index;
determine a plurality of outlines, each cluster in the plurality of clusters being associated with an outline of the plurality of outlines;
generate a grid corresponding to the geological formation, the grid comprising a plurality of cells for each cluster of the plurality of clusters, each cluster of the plurality of clusters having a plurality of cell properties; and
output the grid for the geological formation to a graphical user interface, the grid usable for executing a flow simulation at the graphical user interface.

17. The non-transitory computer readable medium of claim 16, wherein the instructions are further executable by the processor for causing the processor to determine, based on the heterogeneity index, the plurality of cell properties for each cluster of the plurality of clusters, wherein the plurality of cell properties comprise a cell size, a number of cells, and a cell shape.

18. The non-transitory computer readable medium of claim 16, further comprising instructions executable by the processor for causing the processor to:
determine a value of an objective function based on the flow simulation;
determine, based on the value of the objective function, a plurality of updated cell properties for the plurality of cells;
generate, an updated grid comprising a plurality of updated cells having the plurality of updated cell properties; and
output the updated grid for the geological formation to the graphical user interface, the updated grid usable for executing another flow simulation at the graphical user interface.

19. The non-transitory computer readable medium of claim 16, wherein the instructions are further executable by the processor for causing the processor to:
determine a first heterogeneity parameter of the heterogeneity index for a first cluster of the plurality of clusters corresponds to a first number of cells and a first cell size for the first cluster; and
determine a second heterogeneity parameter of the heterogeneity index for a second cluster of the plurality of clusters corresponds to a second number of cells and a second cell size for the second cluster.

20. The non-transitory computer readable medium of claim 16, wherein the instructions are further executable by the processor for causing the processor to determine, by another machine-learning model, the plurality of cell properties for the plurality of cells based on the heterogeneity index.
